(19) United States
(12) Patent Application Publication
(10) Pub. No.: US 2013/0109173 A1
(43) Pub. Date: May 2, 2013

(54) METHODS FOR REMOVING SILICON NITRIDE SPACER, FORMING TRANSISTOR AND FORMING SEMICONDUCTOR DEVICES

(71) Applicant: HUANXIN LIU, Shanghai (CN)

(72) Inventor: HUANXIN LIU, Shanghai (CN)

(73) Assignee: Semiconductor Manufacturing International (Shanghai) Corporation, Shanghai (CN)

(21) Appl. No.: 13/357,613

(22) Filed: Jan. 24, 2012

(30) Foreign Application Priority Data
Oct. 31, 2011 (CN) 201110338466.9

(51) Int. Cl. H01L 21/28

(52) U.S. Cl. 438/655; 257/E21.158

(57) ABSTRACT

A method for removing silicon nitride spacers includes providing a silicon substrate having a gate formed thereon, silicon nitride spacers formed on sidewalls of the gate, and source/drain regions formed in the silicon substrate on both sides of the gate, forming metal layers on the gate and the source/drain regions, and performing a first annealing process in which the metal layers react with the silicon substrate so as to form first metal silicide layers. The method further includes forming protective layers on the first metal silicide layers, placing the silicon substrate into a phosphorous acid solution saturated with silicon ions so as to remove the silicon nitride spacers, and after removing the silicon nitride spacers, performing a second annealing process in which the first metal silicide layers react with the silicon substrate so as to form second metal silicide layers.

### CROSS-REFERENCES TO RELATED APPLICATIONS

The present application claims the priority of Chinese Patent Application No. 201110338466.9, entitled “Methods for Removing Silicon Nitride Spacers, Forming Transistors and Forming Semiconductor Devices”, filed on Oct. 31, 2011, the entire disclosure of which is incorporated herein by reference.

### FIELD OF THE INVENTION

The present invention generally relates to the semiconductor manufacturing field, and more particularly, to methods for removing silicon nitride spacers, forming a transistor and forming a semiconductor device.

### BACKGROUND OF THE INVENTION

With rapid development of semiconductor manufacturing technology, in order to obtain faster operation speeds, lager memory capacities and more functions, semiconductor chips are designed towards higher integration levels. The higher the integration level of the semiconductor chips, the smaller the critical dimensions of semiconductor devices. Recently, with scaling down of the critical dimensions of semiconductor devices, especially when the critical dimensions shrink to 65 nm and beyond, the stress strain technology is adopted into semiconductor manufacturing processes, such as stress proximate technology (SPT).

FIGS. 1 and 2 are schematic cross-sectional views of intermediate structures illustrating a method for forming a transistor in the prior art. The method for forming a transistor in the prior art includes the following steps. Referring to FIG. 1, a substrate 10 having a gate structure formed thereon is provided. The gate structure includes a gate dielectric layer 11, a gate 12 formed on the gate dielectric layer and spacers on sidewalls of the gate 12. The spacers include silicon oxide spacers 131 and silicon nitride spacers 132 on the silicon oxide spacers 131.

Before formation of the spacers, lightly doped source/drain regions (not shown) are formed in the substrate 10 by implanting lightly doped ions into the substrate 10. After the formation of the spacers, a heavily doped source region 141 and a drain region 142 are formed in the substrate 10 by implanting heavily doped ions into the substrate 10.

After formation of the source region 141 and the drain region 142, metal silicide layers 15 are formed on the gate 12, the source region 141 and the drain region 142, and metal plugs (not shown) are formed on the metal silicide layers 15. And the metal silicide layers 15 can reduce the contact resistance of the metal plugs.

After formation of the metal silicide layers 15, the silicon nitride spacers 132 are selectively removed by a SPT etching process. However, the metal silicide layers 15 may be easily removed by the SPT etching process, which may compromise the effect of the metal silicide layers 15 to reduce the contact resistance of the plugs.

In order to solve the problem that the metal silicide layer 15 may be easily removed by the SPT etching process while removing the silicon nitride spacers 132, a method for removing the silicon nitride spacers is disclosed in U.S. Patent Publication No. US2007/0072402A1. The disclosed method includes placing 50 wafers with silicon nitride layers into a phosphorous acid solution at a temperature of about 160° C. After 48 hours the temperature of the phosphorous acid solution drops from about 160° C. to about 140° C., and when the temperature decreases to about 140° C., the phosphorous acid solution is saturated with silicon ions. Then the silicon nitride spacers are removed by placing the silicon nitride spacers into the phosphorous acid solution saturated with silicon ions.

The above described method can greatly reduce loss of the metal silicide layers. However, the wafers need be placed in the phosphorous acid solution for 48 hours so that the temperature of the phosphorous acid solution drops from about 160° C. to about 140° C., which adds process time, lowers production efficiency and increases production cost.

### BRIEF SUMMARY OF THE INVENTION

The present invention can reduce the process time required in removing silicon nitride spacers.

Embodiments of the present invention provide a method for removing silicon nitride spacers. The method includes providing a silicon substrate having a gate formed thereon, silicon nitride spacers formed on sidewalls of the gate, and source/drain regions formed in the silicon substrate on both sides of the gate, forming metal layers on the gate and the source/drain regions, performing a first annealing process in which the metal layers react with the silicon substrate so as to form first metal silicide layers, and forming protective layers on the first metal silicide layers. The method further includes, after forming the protective layers, placing the silicon substrate into a phosphorous acid solution saturated with silicon ions so as to remove the silicon nitride spacers, and after removing the silicon nitride spacers, performing a second annealing process in which the first metal silicide layers react with the silicon substrate so as to form second metal silicide layers, wherein the second metal silicide layers include more silicon than the first metal silicide layers.

In an embodiment, the metal layers include Ni and Pt, the second metal silicide layers include NiSiPt, and the first metal silicide layers include Ni₂SiPt.

In an embodiment, forming the protective layers on the first metal silicide layers includes oxidizing top surfaces of the metal silicide layers to form the protective layers.

In an embodiment, oxidizing the top surfaces of the metal silicide layers includes oxidizing the top surfaces of the metal silicide layers by using DIO₃. In an embodiment, the DIO₃ has a concentration in the range from about 30 ppm to about 85 ppm.

In an embodiment, each of the protective layers has a thickness ranging from about 5 Å to about 15 Å.

In an embodiment, oxidizing the top surfaces of the metal silicide layers by using DIO₃ includes spraying the DIO₃ to the first metal silicide layers for more than 30 seconds by using a single wafer spray machine or placing the silicon substrate with the first metal silicide layers into a DIO₃ rinse tank for more than 3 minutes.

In an embodiment, the first annealing process includes a temperature ranging from about 250° C. to about 350° C. and the second annealing process includes a temperature ranging from about 380° C. to about 500° C.

In an embodiment, the phosphorous acid solution saturated with silicon ions is obtained by placing a predetermined number of wafers having silicide surfaces formed thereon in a phosphorous acid solution for a predetermined period of time until the phosphorous acid solution is saturated with silicon ions.

In an embodiment, the silicide surfaces formed on the wafers include silicon nitride.

In an embodiment, when the phosphorous acid solution has a concentration of about 85% and a volume of about 50 liters; and the wafers have a diameter of about 12 inch, the predetermined number of wafers ranges from about 190 to about 210, each wafer includes a silicon nitride surface having a thickness ranging from about 2400 Å to about 2600 Å, the temperature of the phosphorous acid solution ranges from about 100° C. to about 170° C., and the predetermined time period ranges from about 1 hour to about 3 hours.

In an embodiment, after formation of the phosphorous acid solution saturated with silicon ions, while removing the silicon nitride spacers, the saturated phosphorous acid solution has a constant temperature.

In an embodiment, while removing the silicon nitride spacers, the silicon substrate is placed in the saturated phosphorous acid solution for a period of time ranging from about 2 minutes to about 5 minutes at a temperature of about 165° C.

In an embodiment, silicon oxide spacers are formed between the silicon nitride spacers and the gate.

Embodiments of the present invention further provide a method for forming a transistor. The method for forming a transistor includes removing the silicon nitride spacers by the method disclosed above, and forming a stress layer to cover the silicon substrate and the protective layers after removal of the silicon nitride spacers, wherein when the transistor is a PMOS transistor, the stress layer provides a compressive stress; when the transistor is an NMOS transistor, the stress layer provides a tensile stress.

In an embodiment, the stress layer includes silicon nitride.

Embodiments of the present invention further provide a method for forming a semiconductor device. In an embodiment, the method for forming a semiconductor device includes forming a transistor by the method disclosed above, forming an interlayer dielectric layer to cover the stress layer, etching the interlayer dielectric layer, the stress layer and the protective layers to form contact vias, wherein the contact vias expose the second metal silicide layers. The method also includes forming contact plugs by filling a conductive material into the contact vias.

Compared with the prior art, embodiments of the present invention have many advantages: the protective layers are formed after the formation of the first metal silicide layers before the formation of the second silicide layers. After formation of the protective layers on the first metal silicide layers, the substrate is placed into the saturated phosphorous acid solution so as to remove the silicon nitride spacers. Because the protective layers formed on surfaces of the first metal silicide layers can prevent the phosphorous acid solution from reacting with the first metal silicide layers, the first metal silicide layers are protected. Moreover, the silicon substrate with the first metal silicide layers can be directly placed into the phosphorous acid solution saturated with silicon ions at a temperature of about 160° C. to remove the silicon nitride spacers, and there is no need to wait about 48 hours until the temperature of phosphorous acid solution drops from about 160° C. to about 140° C. After the removal of the silicon nitride spacers, the second metal silicide layers are formed by performing the second annealing process to the substrate. And the second metal silicide layers include metal silicide which is generally used in semiconductor devices and the second metal silicide layers include more silicon than the first metal silicide layers. Moreover, the silicon nitride spacers are removed after the first annealing process and before the second annealing process, and the first metal silicide layers include less silicon, therefore, less silicon may react with the phosphorous acid solution, and the loss of the first metal silicide layers is reduced, even if the protective layers do not have a sufficient thickness.

In the embodiments of the present invention, a predetermined number of wafers are placed into the phosphorous acid solution for a predetermined period of time to make the phosphorous acid solution saturated. Thereafter, the silicon substrate with first metal silicide layers is directly placed into the saturated phosphorous acid solution and there is no need to wait about 48 hours until the temperature of phosphorous acid solution drops from about 160° C. to about 140° C. before removal of the silicon nitride spacers, which can reduce process time and production cost.

Moreover, in the embodiments of the present invention, the temperature of the phosphorous acid solution may range from about 100° C. to about 170° C. When the temperature of phosphorous acid solution ranges from about 140° C. to about 170° C., the temperature of the phosphorous acid solution is greater than that in the prior art. And when the silicon nitride spacers are removed in the phosphorous acid solution at a temperature which is greater than 140° C., the removing rate of the silicon nitride spacers is greater than that in the prior art so that the production efficiency can be further enhanced.

### BRIEF DESCRIPTION OF THE DRAWINGS

FIGS. 1 and 2 are schematic cross-sectional views of intermediate structures illustrating a method for forming a transistor, as known in the prior art;

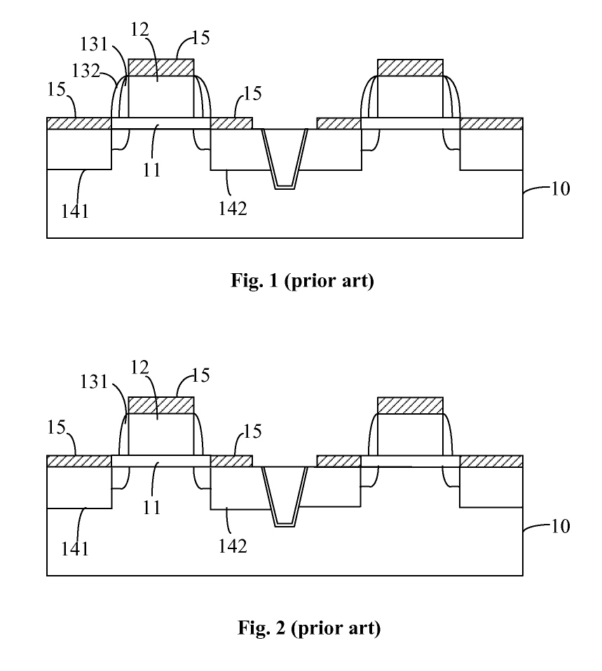

FIG. 3 is a flow chart of a method for removing silicon nitride spacers in an embodiment of the present invention;

FIGS. 4 to 8 are schematic cross-sectional views of intermediate structures illustrating a method for removing silicon nitride spacers according to an embodiment of the present invention;

FIG. 9 is a schematic cross-sectional view of an intermediate structure illustrating a method for forming a transistor according to an embodiment of the present invention; and

FIG. 10 is a schematic cross-sectional view of an intermediate structure illustrating a method for forming a semiconductor device according to an embodiment of the present invention.

### DETAILED DESCRIPTION OF THE INVENTION

The inventor of the present invention discovered that, when 50 wafers having silicon nitride surfaces are placed into a phosphorous acid solution at a temperature of about 160° C. as described in the prior art, there is a need to wait 48 hours for the temperature of the phosphorous acid solution to drop from about 160° C. to about 140° C. because the number of wafers is not sufficiently large to quickly make the phosphorous acid solution saturated. In order to save time and avoid a long wait time for the temperature of the phosphorous acid solution to drop, more wafers having silicon nitride surfaces need to be placed into the phosphorous acid solution, the number of wafers should be sufficiently large to quickly make the phosphorous acid solution saturated at a temperature of about 160° C. However, when a substrate having silicon nitride spacers is directly placed into the saturated phosphorous acid solution at a temperature of about 160° C., the loss of metal silicide is larger than that at a temperature of about 140° C.

Embodiments of the present invention provide a method for removing the silicon nitride spacers, wherein the protective layers are formed after the formation of the first metal silicide layers before the formation of the second silicide layers. After formation of the protective layers on the first metal silicide layers, the substrate is placed into the saturated phosphorous acid solution so as to remove the silicon nitride spacers. Because the protective layers formed on surfaces of the first metal silicide layers can prevent the phosphorous acid solution from reacting with the first metal silicide layers, the first metal silicide layers are protected. Moreover, the silicon substrate with the first metal silicide layers can be directly placed into the phosphorous acid solution saturated with silicon ions at a temperature of about 160° C. to remove the silicon nitride spacers, and there is no need to wait about 48 hours until the temperature of phosphorous acid solution drops from about 160° C. to about 140° C. After the removal of the silicon nitride spacers, the second metal silicide layers are formed by performing the second annealing process to the substrate. And the second metal silicide layers include metal silicide which is generally used in semiconductor devices and include more silicon than the first metal silicide layers. Moreover, the silicon nitride spacers are removed after the first annealing process and before the second annealing process, and the first metal silicide layers include less silicon, therefore, less silicon may react with the phosphorous acid solution, and the loss of the first metal silicide layers is reduced, even if the protective layers do not have a sufficient thickness.

In order to provide a thorough understanding of the above-mentioned and other objectives, features and advantages of the present invention, embodiments of the present invention will be described hereinafter in conjunction with the accompanying drawings.

While specific embodiments and examples are described herein for illustrative purposes, the description of illustrated embodiments is not intended to limit the present invention, many modifications and variations are possible within the scope of this description, as those skilled in the relevant art will recognize.

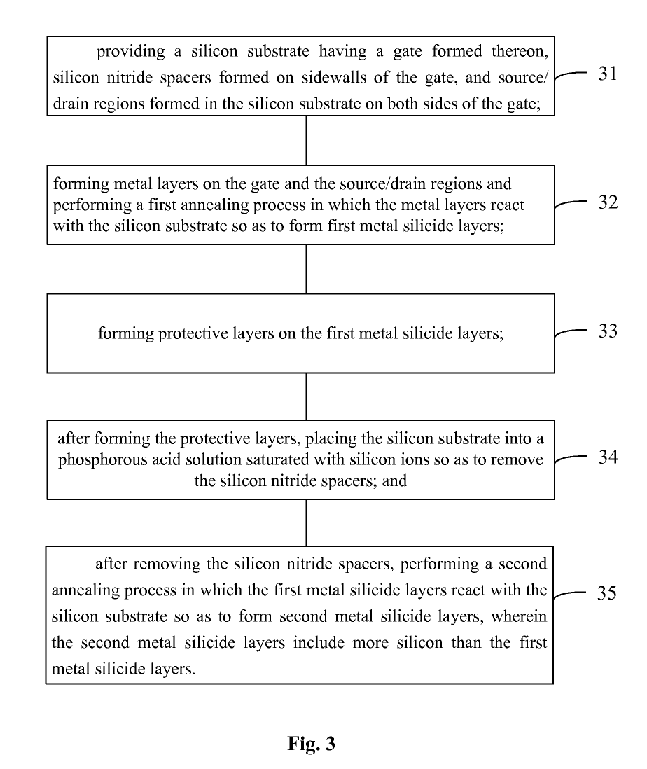

FIG. 3 is a flow chart of a method for removing silicon nitride spacers in an embodiment of the present invention. Referring to FIG. 3, a method for removing silicon nitride spacers in the embodiment includes providing a silicon substrate having a gate formed thereon, silicon nitride spacers formed on sidewalls of the gate, and source/drain regions formed in the silicon substrate on both sides of the gate (step 31), forming metal layers on the gate and the source/drain regions and performing a first annealing process in which the metal layers react with the silicon substrate so as to form first metal silicide layers (step 32). The method further includes forming protective layers on the first metal silicide layers (step 33), and, after forming the protective layers, placing the silicon substrate into a phosphorous acid solution saturated with silicon ions so as to remove the silicon nitride spacers (step 34). The method also includes, after removing the silicon nitride spacers, performing a second annealing process in which the first metal silicide layers react with the silicon substrate so as to form second metal silicide layers, wherein the second metal silicide layers include more silicon than the first metal silicide layers (step 35).

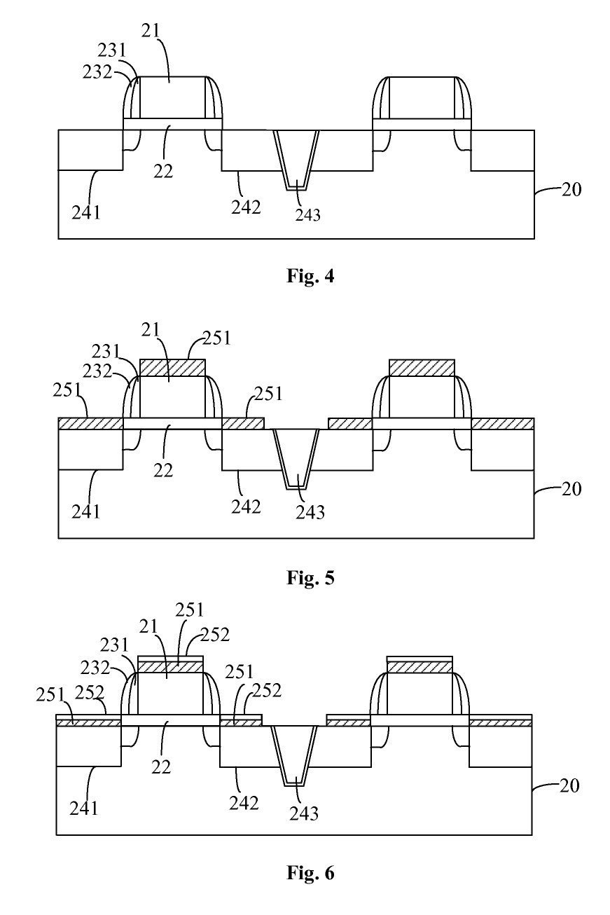

FIGS. 4 through 7 are schematic cross-sectional views of intermediate structures illustrating a method for removing silicon nitride spacers in an embodiment of the present invention. The method for removing the silicon nitride spacers provided in the embodiments of the present invention will be described in detail in conjunction with FIGS. 3 through 7.

Referring to FIGS. 3 and 4, step 31 is performed to provide a silicon substrate 20. The silicon substrate 20 includes a gate 21 formed thereon, silicon nitride spacers 232 formed on sidewalls of the gates 21, and a source region 241 and a drain region 242 formed on each side of the gate 21. In an embodiment, spacers on the sidewalls of the gate 21 include a two-tier structure and silicon oxide spacers 231 are formed between the silicon nitride spacers 232 and the gate 21. It should be noted that the spacers on the sidewalls of the gate 21 may not be limited to a single-layer structure, a two-tier structure, or any other known laminated structures, only if the outmost spacers of the spacer structure on the gate 21 are silicon oxide spacers. The silicon substrate 20 may include monocrystalline silicon or silicon on insulation (SOI). The gate 21 may include polysilicon, metal such as Ti, Co, Ni, Al, W, and the like or other materials well known by those skilled in the art. Moreover, an insulation structure 243 is formed between two adjacent gates which are formed on the silicon substrate. In an embodiment, the insulation structure 243 includes a shallow trench isolation (STI) structure. But the insulation structure 243 is not limited to the STI structure, and it may be any other structures well known by those skilled in the art. In addition, a gate dielectric layer 22 is formed between the gate 21 and the silicon substrate 20. In an embodiment, the gate dielectric layer 22 includes silicon oxide. But the material of the gate dielectric layer 22 is not limited to silicon oxide, and it may be any other materials known to those skilled in the art.

Referring to FIGS. 3 and 5, step 32 is performed. Step 32 forms metal layers on the gate 21, the source region 241 and the drain region 242, and performs a first annealing process in which the metal layers react with the silicon substrate so as to form first metal silicide layers 251.

In an embodiment, the metal layers include Ni and Pt, a temperature of the first annealing process ranges from about 250° C. to about 350° C., and the first metal silicide layers 251 include Ni₂SiPt. In an example embodiment, the metal layers include NiPt and are formed by a physical vapor deposition or any other known processes, and correspondingly, the first metal silicide layers 251 include Ni₂SiPt. However, the material of the metal layers is not limited to NiPt, and the material of the first metal silicide layers is not limited to Ni₂SiPt.

Referring to FIGS. 3 and 6, step S33 is performed to form protective layers 252 on the first metal silicide layers 251. In an embodiment, each of the protective layers has a thickness ranging from about 5 Å to about 15 A. In a specific embodiment, forming the protective layers 252 on the first metal silicide layers 251 includes forming oxidized first metal silicide layers on surfaces of the first metal silicide layers 251 by oxidizing the first metal silicide layers 251, wherein the surfaces of the metal silicide layers 251 are oxidized by DIO₃. The oxidized first metal silicide layers are used as the protective layers 252. In an embodiment, oxidizing the metal silicide layers 251 includes spraying DIO₃ to the first metal silicide layers for about 30 seconds or more by using a single-wafer spray machine. By the above method, the first metal silicide layers are oxidized to form the oxidized first metal silicide layers. In an embodiment, a thickness of each oxidized first metal silicide layer ranges from about 5 Å to about 15 Å. The method for oxidizing the metal silicide layers 251 is not limited to spraying DIO₃, it also can include placing the silicon substrate with the first metal silicide layers into a DIO₃ rinse tank for about 3 minutes or more so that the first metal silicide layers are oxidized to form the oxidized first metal silicide layers which will be used as the protective layers 252, wherein each of the oxidized first metal silicide layers has a thickness ranging from about 5 Å to about 15 Å and the DIO₃ has a concentration ranging from about 30 ppm to about 85 ppm.

It should be noted that, in the embodiments of the present invention, the first metal silicide layers are oxidized to form the oxidized first metal silicide layers and the oxidized first metal silicide layers will be used as the protective layers. Therefore, the process for forming the protective layers is simple and does not require long processing time, which will effect production efficiency.

Moreover, the protective layers are not limited to the oxidized first metal silicide layers and may be additional layers formed on the first metal silicide layers by a vapor deposition process with other materials, only if the formed protective layers can provide protection to the first metal silicide layers and prevent the first metal silicide layers from reacting with the phosphorous acid solution.

Referring to FIGS. 3 and 7, step 34 is performed. In step 34, after formation of the protective layers 252, the silicon nitride spacers are removed by placing the silicon substrate 20 into the saturated phosphorous acid solution. In an embodiment, the phosphorous acid solution saturated with silicon ions is obtained by placing a predetermined number of wafers having silicide surfaces into a phosphorous acid solution for a predetermined period of time until the phosphorous acid solution becomes saturated. In practical operations, the number of wafers and the predetermined time period depend on concentration and volume of the phosphorous acid solution, and type and thickness of the silicide surface. In an example embodiment, the phosphorous acid solution has a concentration of about 85% and a volume of about 50 liters. But the volume of the phosphorous acid solution is not limited to 50 liters and a certain deviation is allowed. In an embodiment, the wafers have a diameter of about 12 inch, the predetermined number of wafers ranges from about 190 to about 210, the predetermined time period ranges from about 1 hour to about 3 hours, the thickness of each silicon nitride surface ranges from about 2400 Å to about 2600 Å, and the temperature of the phosphorous acid solution ranges from about 100° C. to about 170° C. In an example embodiment, when the wafers have a diameter of about 12 inch, the predetermined number of wafers is about 200, the predetermined time is about 1 hour, and the temperature of the phosphorous acid solution is about 165° C. After having conducted several experiments and measurements, it has been found that the activity of the phosphorous acid solution is high when the temperature of the phosphorous acid solution is at about 165° C., so that the hydrolytic reaction of the silicon nitride can be catalyzed more easily at about 165° C.

After formation of the phosphorous acid solution saturated with silicon ions, because the protective layers 252 formed on the first metal silicide layers can provide protection to the first metal silicide layers, the silicon substrate can be directly placed into the saturated phosphorous acid solution and there is no need to wait about 48 hours until the temperature of phosphorous acid solution drops from about 160° C. to about 140° C. In other words, the temperature of the phosphorous acid solution can remain constant while removing the silicon nitride spacers. In an embodiment, while removing the silicon nitride spacers, the temperature of the phosphorous acid solution is kept at about 165° C., and the time period of placing the silicon substrate in the phosphorous acid solution ranges from about 2 minutes to about 5 minutes. In an example embodiment, the time of placing the silicon substrate in the phosphorous acid solution is about 4 minutes. Because the activity of the phosphorous acid solution is high at about 165° C., the silicon nitride spacers can be removed quickly, thereby increasing the processing speed. In practical operations, only if the temperature of phosphorous acid solution is higher than 140° C., the processing speed for removing the silicon nitride spacers will be greater than that in the prior art.

Referring to FIG. 8, the step S35 is performed. In the step 35, after removal of the silicon nitride spacers, second metal silicide layers 253 are formed by performing a second annealing process in which the first metal silicide layers react with the silicon substrate, and the second metal silicide layers 253 include more silicon than the first metal silicide layers 251. In an embodiment, the second annealing process has a temperature ranging from about 380° C. to about 500° C. The second metal silicide layers 253 include NiSiPt, but the material of the second metal silicide layers 253 is not limited to NiSiPt.

In an embodiment, after the removal of the silicon nitride spacers, the second metal silicide layers are formed by performing the second annealing process to the substrate. And the second metal silicide layers include metal silicide which is generally used in semiconductor devices and include more silicon than the first metal silicide layers. Moreover, the silicon nitride spacers are removed after the first annealing process and before the second annealing process, and the first metal silicide layers include less silicon, therefore, less silicon may react with the phosphorous acid solution, and the loss of the first metal silicide layers is reduced, even if the protective layers do not have a sufficient thickness.

It should be noted that, in the embodiments of the present invention, the first metal silicide layers include Ni₂SiPt and the second metal silicide layers include NiSiPt. But the material of the first metal silicide layers is not limited to Ni₂SiPt, the material of the second metal silicide layers is not limited to NiSiPt, and both may be other materials well known by those skilled in the art.

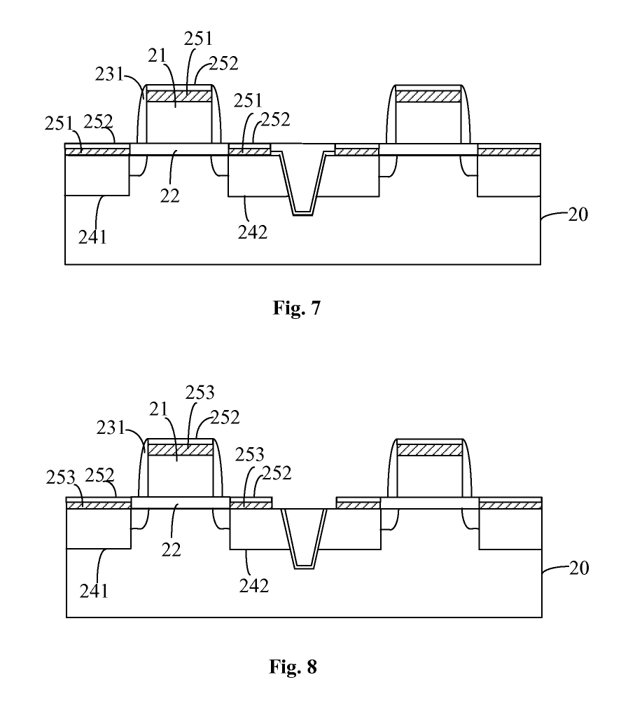

According to the above method for removing the silicon nitride spacers, embodiments of the present invention further provide a method for forming a transistor. In an embodiment, the method for forming a transistor includes: removing the silicon nitride spacers by the method described above; and referring to FIG. 9, forming a stress layer 26 to cover the silicon substrate and the protective layers 252 after removal of the silicon nitride spacers. When the transistor is a PMOS transistor, the stress layer 26 provides a compressive stress; when the transistor is an NMOS transistor, the stress layer 26 provides a tensile stress. The method for forming the stress layer is known to those skilled in the art, and will not be described in detail herein.

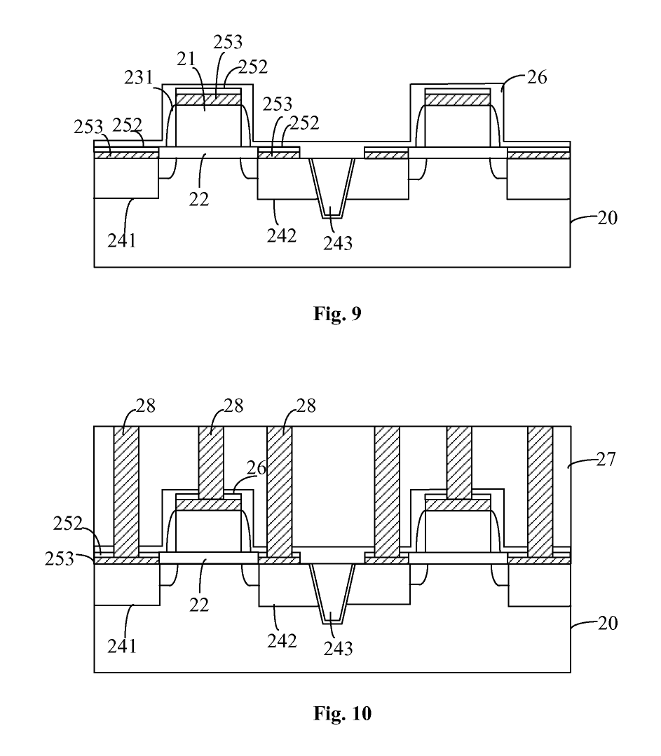

According to the above method for forming a transistor, embodiments of the present invention provide a method for forming a semiconductor device. In an embodiment shown in FIG. 10, the method for forming a semiconductor device includes: forming a transistor by the method described above; forming an interlayer dielectric layer 27 to cover the stress layer 26; etching the interlayer dielectric layer 27, the stress layer 26 and the protective layers 252 so as to form contact vias, wherein the second metal silicide layers 253 are exposed by the contact vias; and forming contact plugs 28 by filling a conductive material into the contact vias.

The protective layers 252 on the second metal silicide layers 253 can prevent the contact plugs from being electrically connected to the source region, the drain region and the gate. But by over etching the interlayer dielectric layer and the stress layer to form the contact vias, the protective layers also are etched and the second metal silicide layers are also exposed, so that the protective layers can not prevent the contact plugs from being electrically connected to the source region, the drain region and the gate. In addition, the second metal silicide layers can further provide an effect to reduce contacting resistances.

Although the present invention has been disclosed as above with reference to preferred embodiments, it is not intended to limit the present invention. Those skilled in the art may modify and vary the embodiments without departing from the spirit and scope of the present invention. Accordingly, the scope of the present invention shall be defined in the appended claim.

1. A method for removing silicon nitride spacers, comprising:
providing a silicon substrate having a gate formed thereon, silicon nitride spacers formed on sidewalls of the gate, and source/drain regions formed in the silicon substrate on both sides of the gate;
forming metal layers on the gate and the source/drain regions;
performing a first annealing process in which the metal layers react with the silicon substrate so as to form first metal silicide layers;
forming protective layers on the first metal silicide layers;
after forming the protective layers, placing the silicon substrate directly into a phosphorous acid solution saturated with silicon ions without waiting to cool the phosphorous acid solution to remove the silicon nitride spacers; and
after removing the silicon nitride spacers, performing a second annealing process in which the first metal silicide layers react with the silicon substrate so as to form second metal silicide layers, wherein the second metal silicide layers include more silicon than the first metal silicide layers.

2. The method according to claim 1, wherein the metal layers comprise Ni and Pt, the first metal silicide layers comprise Ni₂SiPt, and the second metal silicide layers comprise NiSiPt.

3. The method according to claim 1, wherein forming the protective layers on the first metal silicide layers comprises oxidizing top surfaces of the metal silicide layers.

4. The method according to claim 3, wherein oxidizing the top surfaces of the metal silicide layers comprises oxidizing the top surfaces of the metal silicide layers by using DIO₃.

5. The method according to claim 4, wherein the DIO₃ has a concentration ranging from about 30 ppm to about 85 ppm.

6. The method according to claim 3, wherein each of the protective layers has a thickness ranging from about 5 Å to about 15 Å.

7. The method according to claim 3, wherein oxidizing the top surfaces of the metal silicide layers comprises spraying DIO₃ to the first metal silicide layers for more than 30 seconds by using a single wafer spray machine or placing the silicon substrate with the first metal silicide layers into DIO₃ for more than 3 minutes.

8. The method according to claim 1, wherein the first annealing process comprises a temperature ranging from about 250° C. to about 350° C. and the second annealing process comprises a temperature ranging from about 380° C. to about 500 ° C.

9. The method according to claim 1, wherein the phosphorous acid solution saturated with silicon ions is obtained by placing a predetermined number of wafers having suicide surfaces in a phosphorous acid solution for a predetermined period of time until the phosphorous acid solution is saturated with silicon ions.

10. The method according to claim 9, wherein the suicide surfaces on the wafers comprise silicon nitride.

11. The method according to claim 10, wherein when the phosphorous acid solution has a concentration of about 85% and a volume of about 50 liters; and a diameter of the wafers is about 12 inch, the predetermined number of wafers ranges from about 190 to about 210, a thickness of each silicon nitride surface ranges from about 2400 Å to about 2600 Å, the temperature of the phosphorous acid solution ranges from about 100° C. to about 170° C., and the predetermined time period ranges from about 1 hour to about 3 hours.

12. The method according to claim 11, wherein after formation of the phosphorous acid solution saturated with silicon ions, while removing the silicon nitride spacers, a temperature of the phosphorous acid solution remains constant.

13. The method according to claim 1 wherein while removing the silicon nitride space s the silicon substrate is placed into the saturated phosphorous acid solution for a period of time ranging from about 2 minutes to about 5 minutes at a temperature of about 165° C.

14. The method according to claim 1, wherein silicon oxide spacers are formed between the silicon nitride spacers and the gate.

15. A method for forming a transistor, comprising:
providing a silicon substrate having a gate formed thereon, silicon nitride spacers formed on sidewalls of the gate, and source/drain regions formed in the silicon substrate on both sides of the gate;
forming metal layers on the gate and the source/drain regions;
performing a first annealing process in which the metal layers react with the silicon substrate so as to form first metal silicide layers;
forming protective layers on the first metal silicide layers;
after forming the protective layers, placing the silicon substrate directly into a phosphorous acid solution saturated with silicon ions without waiting to cool the phosphorous acid solution to remove the silicon nitride spacers;
after removing the silicon nitride spacers, performing a second annealing process in which the first metal silicide layers react with the silicon substrate so as to form second metal silicide layers, wherein the second metal silicide layers include more silicon than the first metal silicide layers; and
forming a stress layer to cover the silicon substrate and the protective layers after removal of the silicon nitride spacers, wherein the transistor is a PMOS transistor or an NMOS transistor, and wherein the stress layer provides a compressive stress to the PMOS transistor or provides a tensile stress to the NMOS transistor.

16. The method according to claim 15, wherein the stress layer comprises silicon nitride.

17. A method for forming a semiconductor device, comprising:
providing a silicon substrate having a gate formed thereon, silicon nitride spacers formed on sidewalls of the gate, and source/drain regions formed in the silicon substrate on both sides of the gate;
forming metal layers on the gate and the source/drain regions;
performing a first annealing process in which the metal layers react with the silicon substrate so as to form first metal silicide layers;
forming protective layers on the first metal silicide layers;
after forming the protective layers, placing the silicon substrate directly into a phosphorous acid solution saturated with silicon ions without waiting to cool the phosphorous acid solution to remove the silicon nitride spacers;
after removing the silicon nitride spacers, performing a second annealing process in which the first metal silicide layers react with the silicon substrate so as to form second metal silicide layers, wherein the second metal silicide layers include more silicon than the first metal silicide layers;
forming a stress layer to cover the silicon substrate and the protective layers after removal of the silicon nitride spacers, wherein when the transistor is a PMOS transistor or an NMOS transistor, and wherein the stress layer provides a compressive stress to the PMOS transistor or provides a tensile stress to the NMOS transistor;
forming an interlayer dielectric layer to cover the stress layer;
etching the interlayer dielectric layer, the stress layer and the protective layers to form contact vas, wherein the contact vias expose the second metal silicide layers; and
forming contact plugs by filling a conductive material into the contact vias.
